(19) United States
(12) Patent Application Publication
(10) Pub. No.: US 2012/0235697 A1
(43) Pub. Date: Sep. 20, 2012

(54) SYSTEMS AND METHODS OF TESTING SEMICONDUCTOR DEVICES

(75) Inventor: Jaeyoung JANG, Suwon- si (KR)

(73) Assignee: Samsung Electronics Co., Ltd, Suwon-si (KR)

(21) Appl. No.: 13/417,688

(22) Filed: Mar. 12, 2012

(30) Foreign Application Priority Data
Mar. 14, 2011 (KR) 10-2011-0022445

(51) Int. Cl. G01R 31/26

(52) U.S. Cl. 324/754.03; 324/756.03

(57) ABSTRACT

Systems and methods of testing semiconductor devices, the system including a tester configured to evaluate electrical characteristics of a semiconductor device provided on a wafer, and a probe unit configured to transfer electrical signals used to test the semiconductor device between the tester and the semiconductor device. The probe unit may include: a housing; a wafer supporting member disposed in the housing to support the wafer; a printed circuit board disposed on the housing to transfer the electrical signals from and to the tester, and a probe card disposed opposite the wafer supporting member, in the housing. The probe card may include probe pins to deliver the electrical signal from and to the semiconductor device. Each of the probe pins may include a probe tip configured to adjustably extend to contact the wafer.

### CROSS-REFERENCE TO RELATED APPLICATIONS

This U.S. non-provisional patent application claims priority under 35 U.S.C.§119 to Korean Patent Application No. 10-2011-0022445, filed on Mar. 14, 2011, in the Korean Intellectual Property Office, the entire contents of which are hereby incorporated by reference.

### BACKGROUND

1. Field

Exemplary embodiments of the present general inventive concept relate to systems and methods of testing electrical characteristics of a semiconductor device.

2. Description of the Related Art

Generally, a semiconductor fabricating process includes an electrical die sorting (EDS) process for testing electric characteristics of semiconductor devices integrated on a wafer.

The EDS process includes measuring circuit characteristics or operational reliability of a semiconductor device, and evaluating the measured data to sort and mark whether the semiconductor devices are saleable or not. The EDS process may be performed using a testing system configured to apply/measure electric signals to/from semiconductor devices integrated on a wafer and to evaluate salability of the semiconductor devices. The testing system for the EDS process may include a tester generating electrical signals and a probe card with probe tips. During the EDS process, the probe tip may be in contact with the wafer, thereby serving as an electrical path between the tester and the semiconductor devices.

### SUMMARY

Exemplary embodiments of the present inventive concept provide systems and methods configured to test electrical characteristics of a semiconductor device with high efficiency.

Additional aspects and advantages of the present general inventive concept will be set forth in part in the description which follows and, in part, will be obvious from the description, or may be learned by practice of the general inventive concept.

According to exemplary embodiments of the present inventive concept, a semiconductor device testing system may include a tester configured to evaluate electrical characteristics of a semiconductor device provided on a wafer, and a probe unit configured to deliver electrical signals used to test the semiconductor device, between the tester and the semiconductor device. The probe unit may include a housing, a wafer supporting member disposed in the housing and configured to support the wafer, a printed circuit board disposed on the housing to transfer the electrical signals, and a probe card disposed opposite the wafer supporting member in the housing. The probe card may include a plurality of probe pins to transfer the electrical signals to a semiconductor device provided on a wafer. Each of the probe pins may include a probe tip configured to adjustably contact the wafer.

According to various embodiments of the general inventive concept, a method of testing a semiconductor device may include evaluating electrical characteristics of a wafer using a probe card provided with probe tips. Here, a density of the probe tips may be greater than that of electrode pads provided on the wafer to be tested. Furthermore, the evaluating of electrical characteristics of the wafer is performed using a portion of the probe tips classified as active probe tips, while the remaining ones of the probe tips are classified as inactive probe tips that are not used to evaluate electrical characteristics of the wafer.

According to various embodiments, provided is a system to test a semiconductor device, including: a printed circuit board; and a probe card configured to transfer electrical signals between the printed circuit board and a semiconductor device, the probe card including a supporting board and probe pins disposed in the supporting board, the probe card configured to divide the probe pins into active probe pins that deliver the electrical signals to the semiconductor device and inactive probe pins that do not deliver the electrical signals to the semiconductor device, according to the configuration of the semiconductor device.

### BRIEF DESCRIPTION OF THE DRAWINGS

Example embodiments will be more clearly understood from the following brief description taken in conjunction with the accompanying drawings. FIGS. 1-21 represent non-limiting, example embodiments as described herein. These and/or other features and utilities of the present general inventive concept will become apparent and more readily appreciated from the following description of the exemplary embodiments, taken in conjunction with the accompanying drawings, of which:

FIG. 1 is a schematic plan view of a wafer provided with semiconductor devices;

FIG. 2 is an enlarged plan view of a portion “A” of FIG. 1;

FIG. 3 is a schematic diagram of a semiconductor device testing system, according to an exemplary embodiment of the general inventive concept;

FIG. 4 is a schematic sectional view of a probe unit, according to an exemplary embodiment of the general inventive concept;

FIG. 5 is a schematic top plan view of a printed circuit board, according to an exemplary embodiment of the general inventive concept;

FIG. 6 is a schematic bottom plan view of a printed circuit board, according to an exemplary embodiment of the general inventive concept;

FIG. 7 is a schematic sectional view of a printed circuit board, according to an exemplary embodiment of the general inventive concepts;

FIG. 8 is a schematic top plan view of a probe card, according to an exemplary embodiment of the general inventive concept;

FIG. 9 is a schematic bottom plan view of a probe card, according to exemplary embodiment of the general inventive concept;

FIG. 10 is a schematic sectional view of a probe card, according to an exemplary embodiment of the general inventive concept;

FIG. 11 is a schematic sectional view of a probe pin, according to an exemplary embodiment of the general inventive concept;

FIG. 12 is a diagram illustrating an operation of a probe pin, according to exemplary embodiment of the general inventive concept;

FIG. 13 is a schematic sectional view of a printed circuit board engaged with a probe card, according to an exemplary embodiment of the general inventive concept;

FIG. 14 is a diagram illustrating an operation of a printed circuit board and a probe card, according to an exemplary embodiment of the general inventive concept;

FIGS. 15 through 20 are diagrams exemplarily illustrating example methods of using the probe tips as active probe tips; and

FIG. 21 is a schematic sectional view of a printed circuit board engaged with a probe card, according to an exemplary embodiment of the general inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE EXEMPLARY EMBODIMENTS

Example embodiments of the general inventive concept will now be described more fully with reference to the accompanying drawings, in which exemplary embodiments are shown. Exemplary embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, exemplary embodiments of the general inventive concept should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

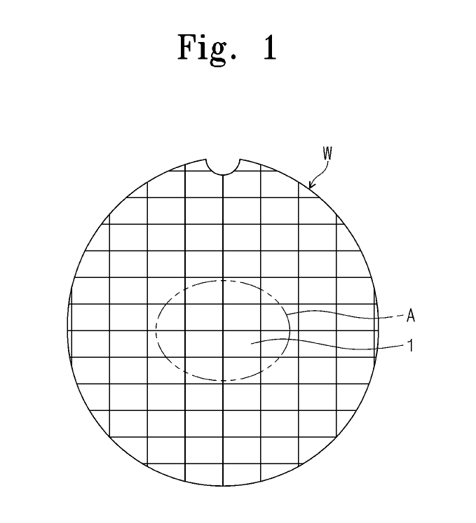

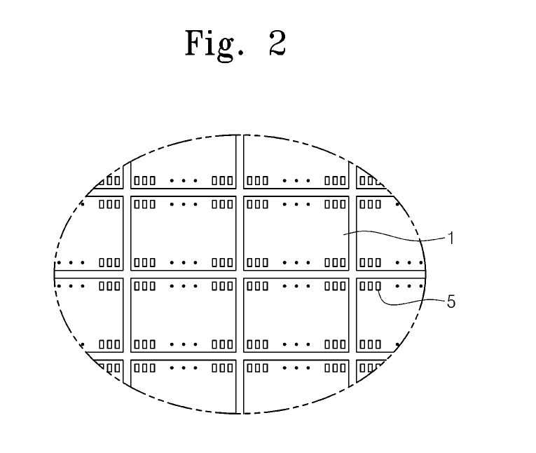

FIG. 1 is a schematic plan view of a wafer provided with semiconductor devices. FIG. 2 is an enlarged plan view schematically illustrating portion “A” of FIG. 1.

Referring to FIGS. 1 and 2, one or more semiconductor devices 1 may be integrated on a wafer W by a chip fabricating process. Thereafter, an electrical die sorting (EDS) process may be performed to test electrical characteristics of the semiconductor devices 1. The EDS process may include applying/measuring electrical signals to/from the semiconductor devices 1, to evaluate whether each of the semiconductor devices 1 is saleable or not. As shown in FIG. 2, each of the semiconductor devices 1 may include electrode pads 5 formed on a top surface thereof, and the electrical signals used in the EDS process may be delivered to/from internal circuit(s) of the semiconductor device 1, via the electrode pads 5.

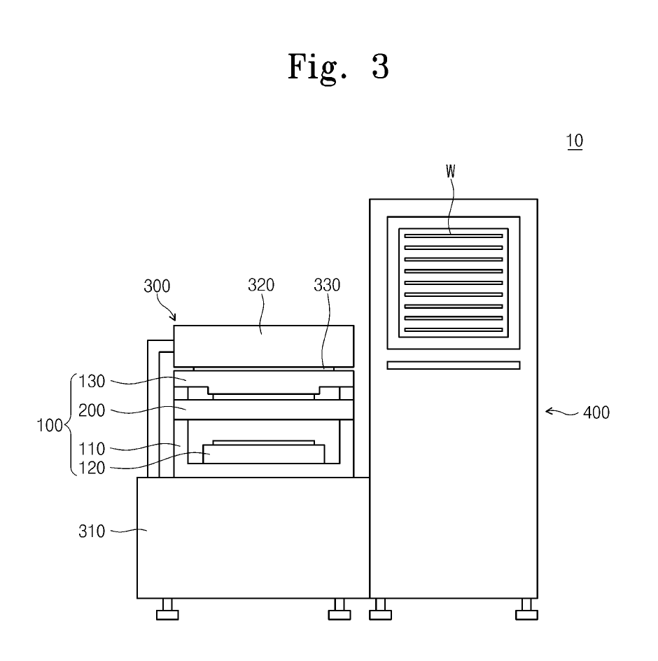

FIG. 3 is a schematic diagram of a semiconductor device testing system 10, according to an exemplary embodiment of the inventive concept. Referring to FIG. 3, the semiconductor device testing system 10 may include a probe unit 100, a tester 300, and a loader 400. The probe unit 100 may be configured to test electrical characteristics of the semiconductor devices 1. The probe unit 100 may be disposed adjacent to the loader 400.

The tester 300 may be disposed adjacent to the probe unit 100. The tester 300 may include a tester body 310 and a tester head 320. The tester body 310 may be configured to generate electrical signals for electrically testing the semiconductor device 1. The tester head 320 may include a base 330 configured to contact the probe unit 100. The tester head 320 may be configured to apply electrical signals generated by the tester body 310 to the probe unit 100, via the base 330, and to receive electrical signals returned from the probe card 300. The electrical signals returned from the probe card 300 may contain information on the salability of the semiconductor devices 1.

The loader 400 may be configured to hold at least one wafer W adjacent to the tester 300. The loader 400 may be configured to deliver the wafer W to, remove the wafer W from, the probe unit 100.

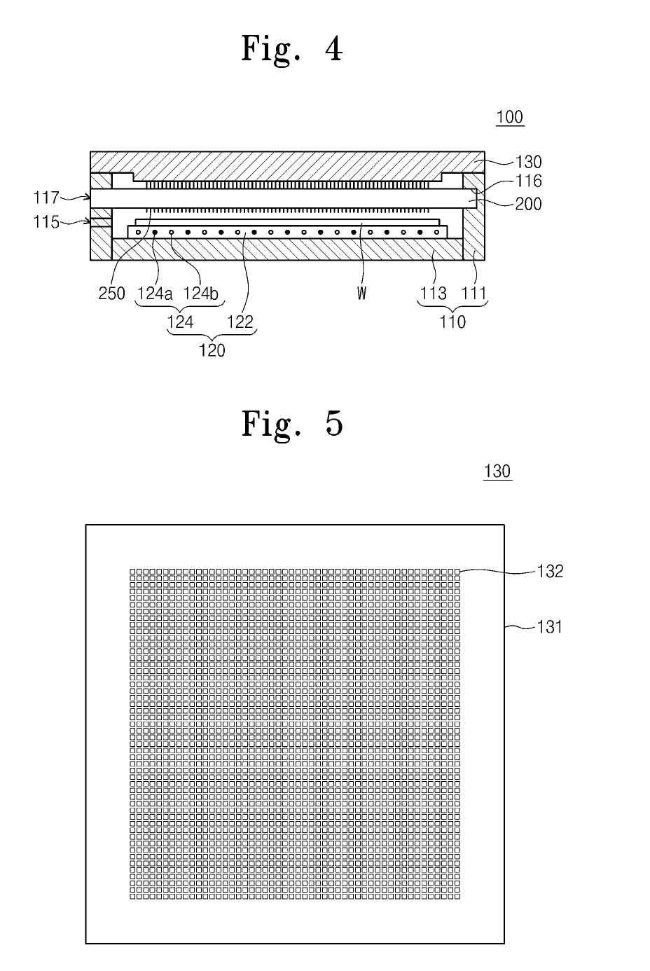

FIG. 4 is a schematic sectional view of a probe unit 100, according to an exemplary embodiment of the inventive concept. FIG. 4 may be a schematic sectional view of the probe unit 100 of FIG. 3. Referring to FIG. 4, the probe unit 100 may include a housing 110, a wafer supporting member 120, a printed circuit board 130, and a probe card 200.

The housing 110 may be configured to provide a space for housing the wafer W during electrical testing of the semiconductor devices 1. The housing 110 may be disposed adjacent to the loader 400.

The housing 110 may be configured to have a top-open structure, and the housing 110 may include sidewalls 111 and a bottom 113. The sidewalls 111 may include a first sidewall adjacent to the loader 400, a second sidewall and a third sidewall extending transversely from the first sidewall, and a fourth sidewall disposed opposite the first sidewall. The sidewalls 111 may be configured to include a wafer gateway 115 and a probe card gateway 117.

The wafer gateway 115 may be provided on the first sidewall. Using a wafer delivering member (not shown) equipped in the loader 400, the wafer W in the loader 400 may be delivered into the housing 110, via the wafer gateway 115.

The probe card gateway 117 may be configured to enable the probe card 200 to move into or out of the housing 110. The probe card gateway 117 may be provided on the first sidewall or the second sidewall.

The housing 110 may include a joining groove 116 in which the probe card 200 may be inserted. If the probe card gateway 117 is provided on the first sidewall, the joining groove 116 may be provided on internal surfaces of the second, third, and fourth sidewalls. Alternatively, if the probe card gateway 117 is provided on the second sidewall, the joining groove 116 may be provided on internal surfaces of the first, third, and fourth sidewalls. The probe card 200 may be inserted into the joining groove 116 when equipped in the housing 110.

The wafer supporting member 120 may be fixed in the housing 110. The wafer supporting member 120 may include a plate 122 and a temperature controlling device 124.

The wafer W may be loaded on a top surface of the plate 122. The plate 122 may be rotated relative to the sidewalls 111 of the housing 110. Due to the rotation of the plate 122, the electrode pads 5 of the semiconductor device of the wafer W can be aligned with probe pins 250 of the probe card 200.

The temperature controlling device 124 may be configured to control the temperature of the wafer W. In this case, electrical characteristics of the semiconductor device 1 may be tested under a variety of temperature conditions. The temperature controlling device 124 may be disposed within the plate 122 and may include a heating part 124a and a cooling part 124b. The heating part 124a may be configured to heat the plate 122 and the wafer W to a high temperature. The cooling part 124b may be configured to cool the plate 122 and the wafer W to a low temperature. Furthermore, the heating and cooling parts 124a and 124b may be configured to maintain the respective temperature conditions.

The heating part 124a may be coil-shaped and may be disposed coplanar with the plate 122. The cooling part 124b may be coil-shaped and may be disposed adjacent to, and coplanar with, the heating part 124a.

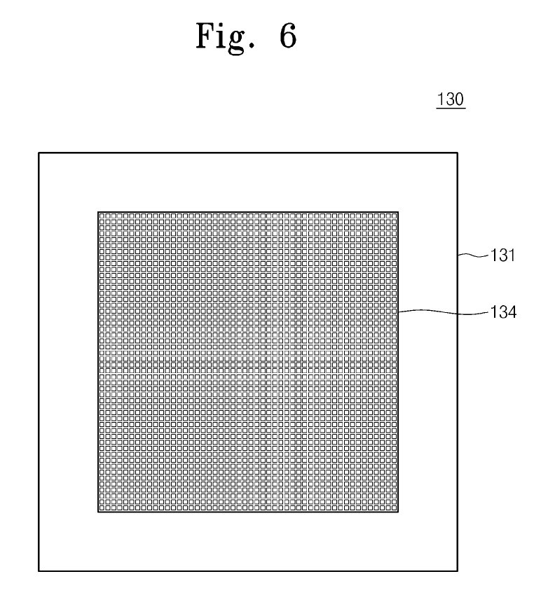

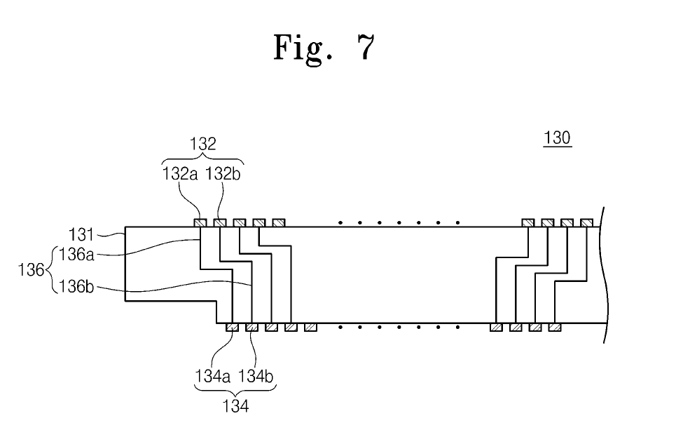

FIGS. 5 through 7 are a top plan view, a bottom plan view, and a schematic sectional view, respectively, illustrating a printed circuit board 130, according to an exemplary embodiment of the inventive concept. FIGS. 5 through 7 may be schematic diagrams illustrating the printed circuit board 130 of FIG. 4. Referring to FIGS. 4 through 7, the printed circuit board 130 may be configured to enable the tester 300 and the probe card 200 to exchange electrical signals associated with the electrical testing of the semiconductor device.

The printed circuit board 130 may be disposed in an upper portion of the housing 110. The printed circuit board 130 may include a plate 131, an upper terminal 132, a lower terminal 134, and a signal interconnection line 136.

The plate 131 may have any suitable plate shape. For example, when viewed from above as shown in FIG. 5, the plate 131 may have rectangular shape. However, the present general inventive concept is not limited to any particular shape. In other words, the plate 131 may have one of a variety of plate shapes.

A plurality of the upper terminals 132 may be disposed on a top surface of the printed circuit board 130. The upper terminals 132 may be configured to contact the tester head 320. As a result, the upper terminals 132 may be electrically connected to the tester head 320. In particular, the upper terminals 132 may be connected to corresponding terminals of the tester head 320. It is possible that the upper terminal 132 may include a connector or a pad.

A plurality of the lower terminals 134 may be disposed on a bottom surface of the printed circuit board 130. The lower terminals 134 may be configured to contact corresponding portions of the probe card 200. As a result, the lower terminals 134 may be electrically connected to the probe card 200. It is possible that the lower terminal 134 comprises an electrode pad.

A plurality of the signal interconnection lines 136 may be disposed in the printed circuit board 130. The upper terminals 132 and the lower terminals 134 may be electrically connected with each other, via the signal interconnection lines 136.

The electrical signals may be delivered from the tester head 320 to the lower terminal 134, via the upper terminal 132 and the signal interconnection line 136 and thereafter delivered to the probe card 200 connected to the lower terminal 134.

It is possible that each of the upper terminals 132 may be connected to a corresponding one of the signal interconnection lines 136. Each of the signal interconnection lines 136 may be connected to a corresponding one of the lower terminals 134. In other words, each of the upper terminals 132 may be electrically coupled to the corresponding the lower terminal 134, via the corresponding the signal interconnection line 136. In various embodiments, it is possible to prevent any electrical cross talk from occurring between the upper terminals 132, between the lower terminals 134, and/or between the signal interconnection lines 136.

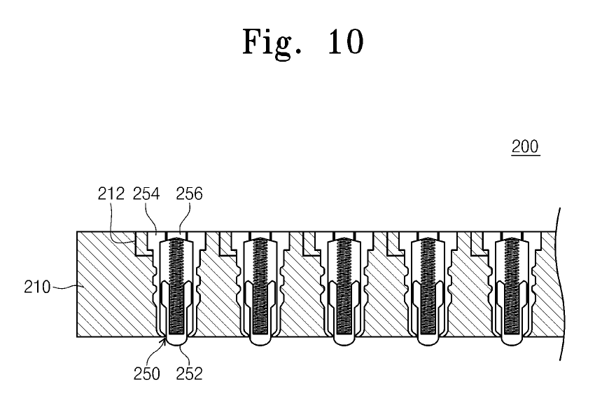

The electrical signals delivered to the probe card 200 may include a first electrical signal used for testing the electrical characteristics of the semiconductor device 1 and a second electrical signal used for changing a position of the probe tip(s) 252 (FIG. 10) relative to the wafer W. In this case, the upper terminals 132, the lower terminals 134, and the signal interconnection lines 136 may include a first upper terminal 132a, a first lower terminal 134a, and a first line 136a, respectively, for delivering the first electrical signal, and a second upper terminal 132b, a second lower terminal 134b, and a second line 136b, respectively, for delivering the second electrical signal.

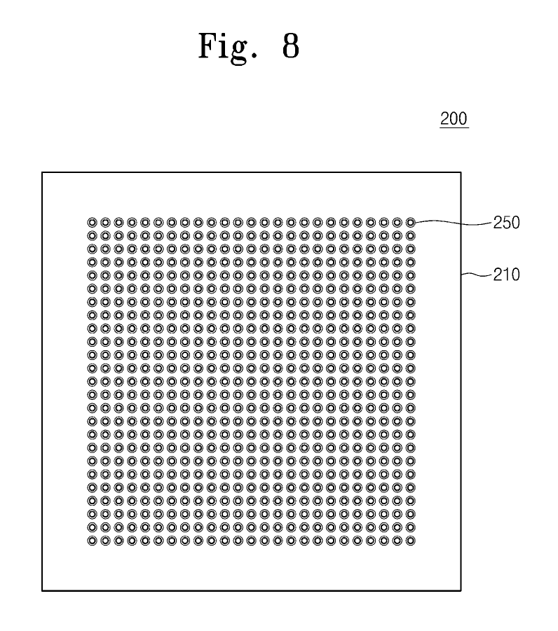

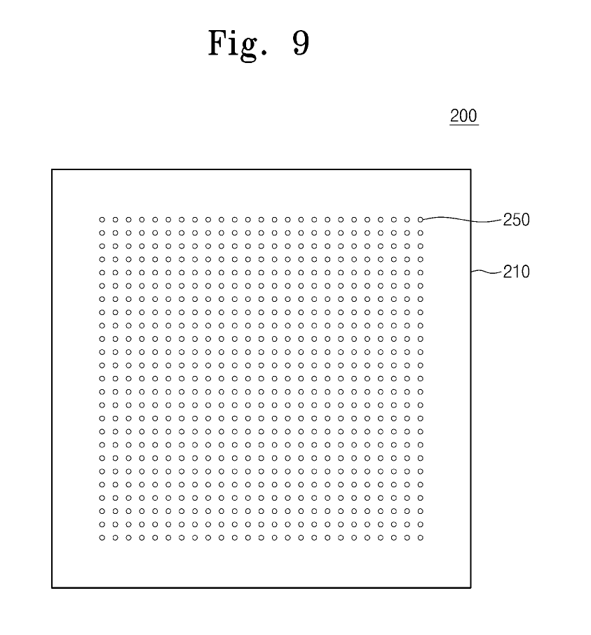

FIGS. 8 through 10 are respectively a top plan view, a bottom plan view, and a schematic sectional view, illustrating the probe card 200 of FIG. 4, according to an exemplary embodiment of the general inventive concept. Referring to FIGS. 2 and 8 through 10, the probe card 200 may be configured to apply the electrical signals from the printed circuit board 130 to the electrode pads 5 of the semiconductor device 1.

The probe card 200 may be used to examine a variety of wafers that differ from each other in terms of the arrangements and numbers of semiconductor devices and/or electrode pads thereof.

The probe card 200 and the wafer supporting member 120 may be disposed on opposing sides of the wafer W. The probe card 200 may include a supporting board 210 and probe pins 250.

The supporting board 210 may have any suitable plate shape. For example, when viewed from above as shown in FIG. 8, the supporting board 210 may be rectangular. However, the present inventive concept is not limited to any particular shape. The supporting board 210 may have a plurality of through holes. Each of the probe pins 250 may be inserted in a corresponding one of the through holes. The supporting board 210 may be inserted into the joining groove 116, through the probe card gateway 114 of the housing 110. The supporting board 210 may be combined with the probe pins 250, as discussed below. The supporting board 210 may further include signal interconnection lines 212 configured to deliver the electrical signals to the probe pins 250.

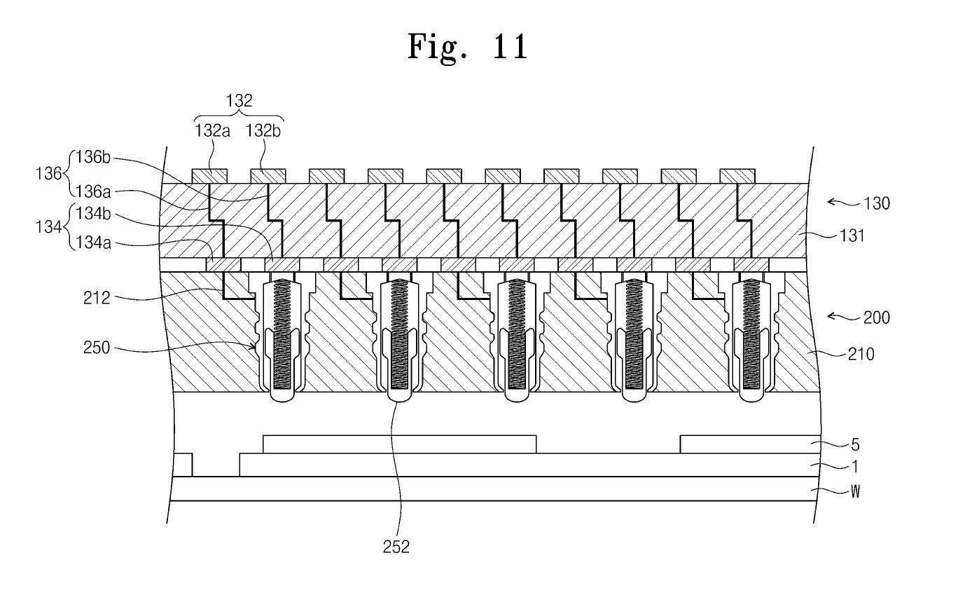

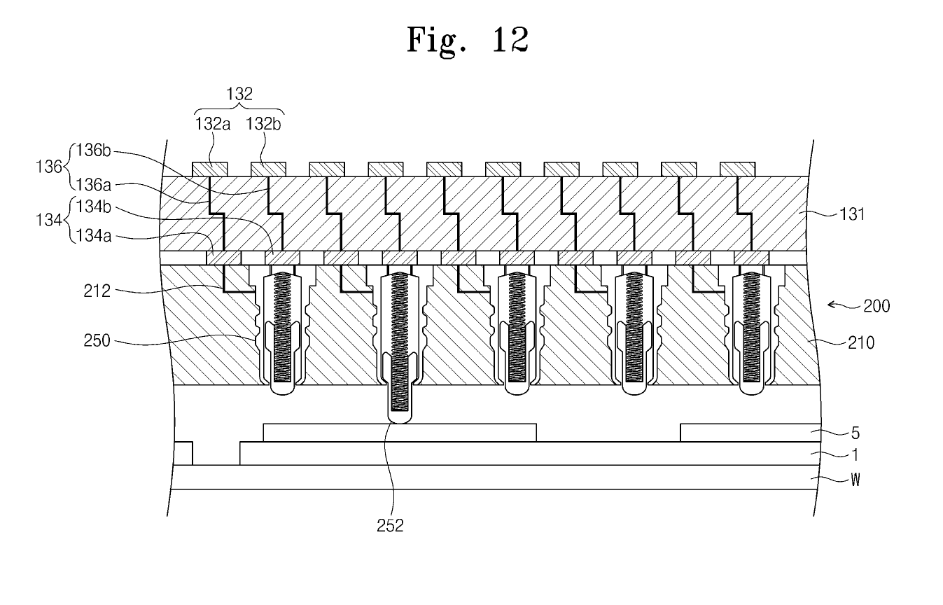

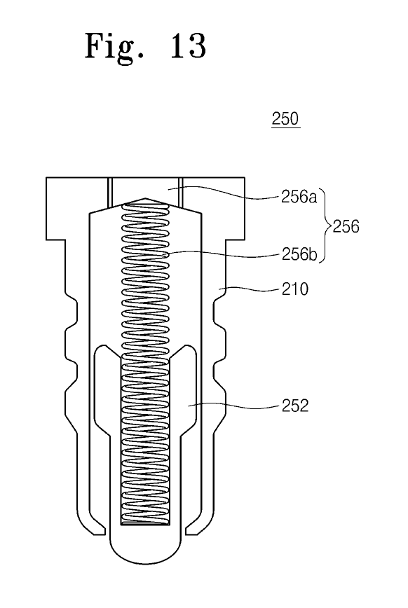

FIGS. 11 and 12 are diagrams schematically illustrating an operation of the probe pins 250 of FIG. 10, and FIG. 13 is a sectional view of a probe pin 250, according to exemplary embodiments of the inventive concept. Referring to FIGS. 10 through 13, the probe pins 250 may be configured to apply the electrical signal to the electrode pads 5 of the semiconductor device 1 integrated on the wafer W. The probe pins 250 may be in contact with the electrode pads 5, respectively. The probe pins 250 may be inserted into the supporting board 210. The probe card 200 may include a plurality of the probe pins 250, which may be arranged in a matrix or lattice shape on the supporting board 210. It is possible that, the density of the probe pins 250, i.e., the number of the probe pins 250 per unit area, may be greater than that of the electrode pads 5 provided on the wafer W. As such, the probe card 200 may include a number of the probe pins 250 that is greater than a number of the electrode pads 5 included on the wafer.

Each probe pin 250 may include a probe tip 252, an outer body 254, and a pressure applying member 256. The probe tip 252 may be configured to contact the electrode pad 5. The first electrical signal used for testing the electrical characteristics of the semiconductor device 1 may be directly applied to the semiconductor device 1, via the probe tip 252. The probe tip 252 may have an open-top, cylindrical shape. The pressure applying member 256 may be inserted into the probe tip 252, via the open top. An outer bottom surface of the probe tip 252 may contact the electrode pad 5, and an internal bottom surface of the probe tip 252 may be combined with the pressure applying member 256. The probe tips 252 may each be classified as an active probe tip or an inactive probe tip, depending on whether or not they are used to test electrical characteristics of a wafer loaded on the wafer supporting member 120.

The outer body 254 may have a pipe shape and may surround a sidewall of the probe tip 252. A sidewall of the outer body 254 may be fastened to the supporting board 210. The outer body 254 and the probe tip 252 may have a structure to physically or electrically contact each other. The first electrical signal may be delivered to the outer body 254 from the corresponding signal interconnection line 212, and then to the probe tip 252, via a contact surface between the outer body 254 and the probe tip 252.

The pressure applying member 256 may be configured to change a vertical position of the probe tip 252. For example, the probe tip 252 may be moved upward or downward by the pressure applying member 256. The pressure applying members 256 may be configured to enable the probe tips 252 to move independently with respect to each other. For example, each of the pressure applying members 256 may be configured to selectively change a vertical position of the corresponding the probe tip 252. The pressure applying member 256 may be disposed within the outer body 254 and combined with the corresponding probe tip 252. The pressure applying member 256 may be elongated or contracted along the longitudinal direction thereof, to change a vertical position of the probe tip 252. An upper portion of the pressure applying member 256 may contact the second lower terminal 134b of the printed circuit board 130. The pressure applying member 256 may be elongated or contracted, in response to the electrical signal delivered from the second lower terminal 134b.

Referring to FIG. 13 in particular, the pressure applying member 256 may include a contact portion 256a and an extension portion 256b. The contact portion 256a may be combined with an upper portion of the extension portion 256b. A lower portion of the extension portion 256b may be combined with the internal bottom surface of the probe tip 252. The second electrical signal may be delivered to the extension portion 256b, via the contact portion 256a, which contacts the second lower terminal 134b. When the second electrical signal is applied to the extension portion 256b, the extension portion 256b may be elongated along the longitudinal direction thereof.

The pressure applying member 256 may include a piezoelectric element capable of being elongated or contracted along the longitudinal direction thereof, in response to the electrical signal. However, the present general inventive concept is not limited thereto. The pressure applying member 256 may be shaped in a variety of forms that can exhibit an elongation and/or contraction, along the longitudinal direction thereof. For example, the pressure applying member 256 may be shaped like a spring.

The outer body 254 of the probe pin 250 may partially cover an upper a sidewall of the probe tip 252. As described above, the first electrical signal may be delivered to the probe tip 252, via the interface between the outer body 254 and the probe tip 252. The pressure applying member 256 may be electrically isolated from the outer body 254 and the probe tip 252. As a result, the second electrical signal delivered to the pressure applying member 256 may not be affected by the first electrical signal delivered to the outer body 254 and the probe tip 252.

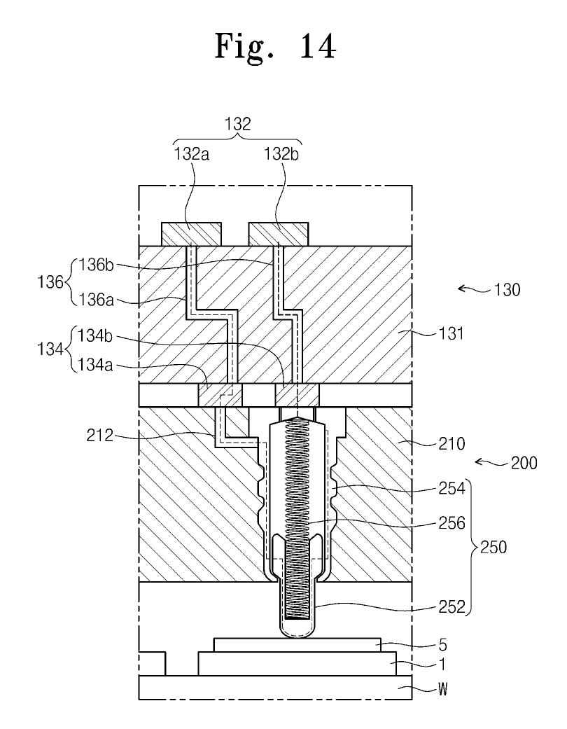

FIG. 14 is a schematic sectional view of a printed circuit board 130 engaged with a probe card 200, according to an exemplary embodiment of the inventive concept. Referring to FIG. 14, the printed circuit board 130 may contact a top surface of the probe card 200, via the lower terminal 134.

The first electrical signal used to test electrical characteristics of the semiconductor device 1 may be delivered to the probe pin 250 via the first upper terminal 132a, the first line 136a, and the first lower terminal 134a. The second electrical signal used for moving the probe tip 252 may be delivered to the probe pin 250, via the second upper terminal 132b, the second line 136b, and the second lower terminal 134b.

The first and second electrical signals may both be delivered to corresponding ones of the probe pins 250. In other words, each probe pin 250 may be electrically coupled to one first lower terminal 134a and one second lower terminal 134b. The first lower terminal 134a may be in contact with the signal interconnection line 212 of the supporting board 210, which is connected to the outer body 254 of the probe pin 250. The second lower terminal 134b may be in contact with an upper portion of the pressure applying member 256 of the probe pin 250.

The first electrical signal may be delivered to the probe tip 252, via the outer body 254. As described above, a probe tip 252 applied with the first electrical signal may be referred to as an active probe tip, which is used to test electrical characteristics of the semiconductor device 1. The second electrical signal may be applied to the probe pin 250 with the first electrical signal. The pressure applying member 256 applied with the second electrical signal may be elongated, such that the corresponding electrode tip 252 contacts the electrode pad 5 disposed thereunder. As a result, the first electrical signal may be delivered to the electrode pad 5 via the active probe tip.

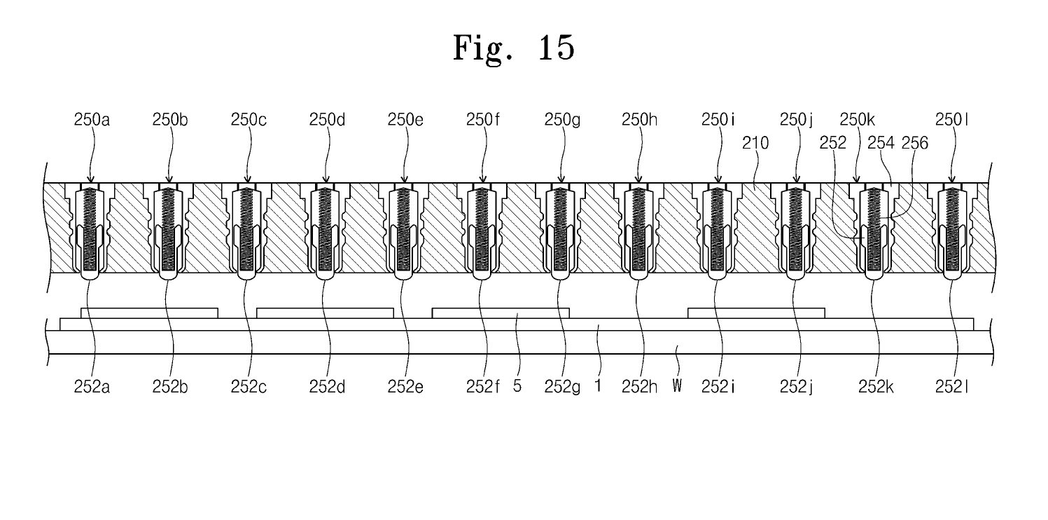

FIGS. 15 through 20 are diagrams illustrating exemplarily methods of using the probe tips 252 referred to as the active probe tips. As described with reference to FIGS. 15 through 20, different probe tips 252 may be selected as the active probe tips, depending on the type of the wafer W to be tested.

Referring to FIGS. 15 through 20, the arrangement and/or number of electrode pads 5 on the semiconductor device 1 may vary, depending on the type of wafer W. The density of the probe pins 250 provided on the supporting board 210 may be greater than that of the electrode pad 5. As a result, various types of wafers W may be tested using the probe card 200.

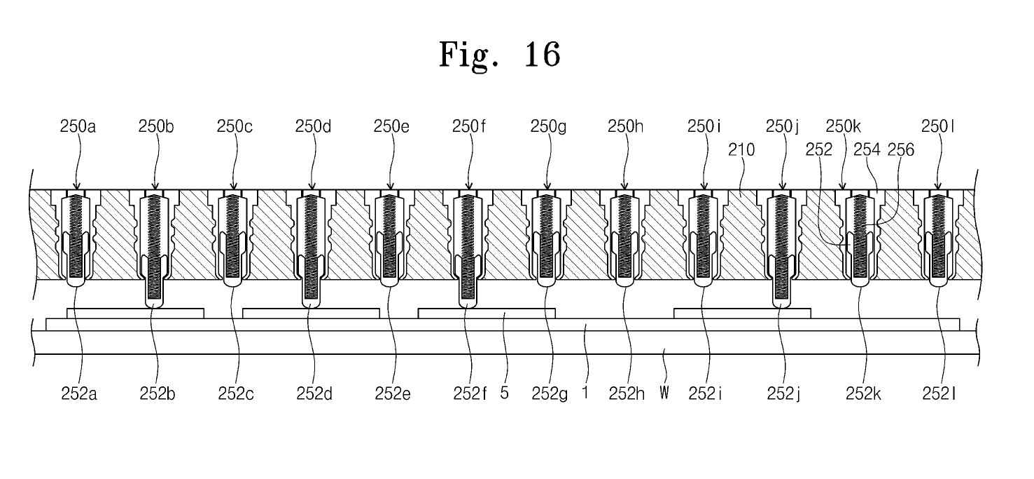

For the wafer W shown in FIG. 15, first and second electrical signals generated by the tester 300 may be delivered to some of the probe tips (e.g., probe tips 250b, 250d, 250f, and 250j, which are disposed over the electrode pads 5). As shown in FIG. 16, the probe tips 250b, 250d, 250f and 250j may be referred to as active probe tips. The pressure applying members 256 of the active probe tips may be elongated in response to the second electrical signals. Thus, the active probe tips may contact the corresponding electrode pads 5. The first electrical signals may then be delivered to the electrode pads 5, via the active probe tips.

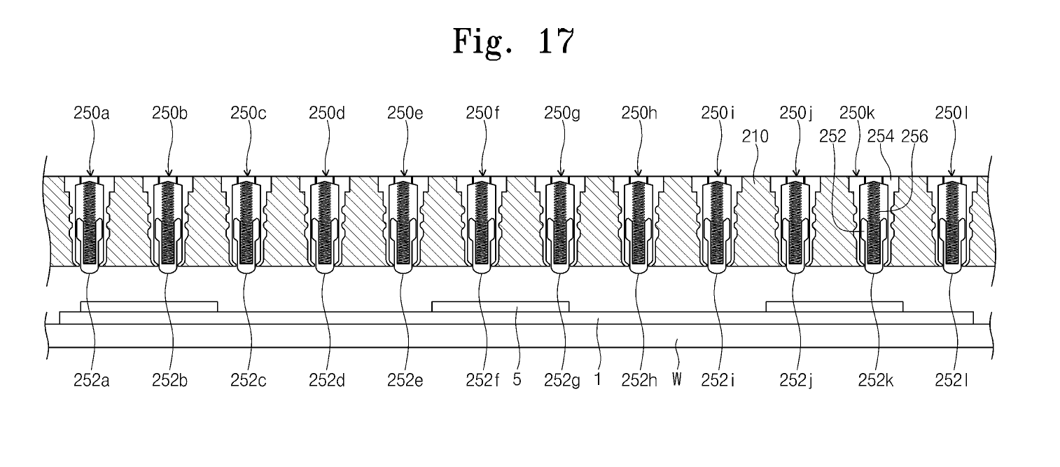

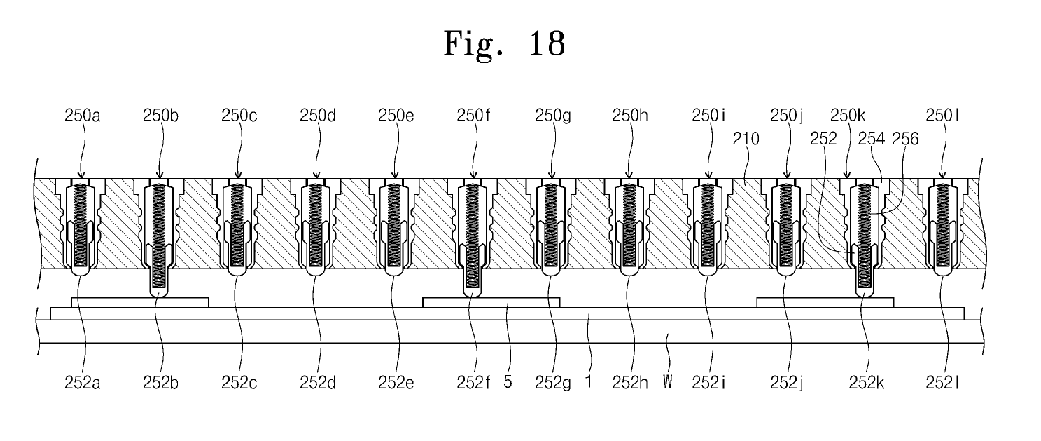

The wafer W shown in FIG. 17 differs from the wafer W of FIG. 15, in terms of the arrangement and number of the electrode pads 5. In this case, the first and second electrical signals generated by the tester 300 may be delivered to selected probe tips 252b, 252f, and 252k that are disposed over the electrode pads 5. Thus, as shown in FIG. 18, the probe tips 252b, 252f, and 252k may be referred to as active probe tips. The pressure applying members 256 of the active probe tips may be elongated in response to the second electrical signals. Thus, the active probe tips may contact the corresponding electrode pads 5. Then, the first electrical signals may be delivered to the electrode pads 5, via the active probe tips.

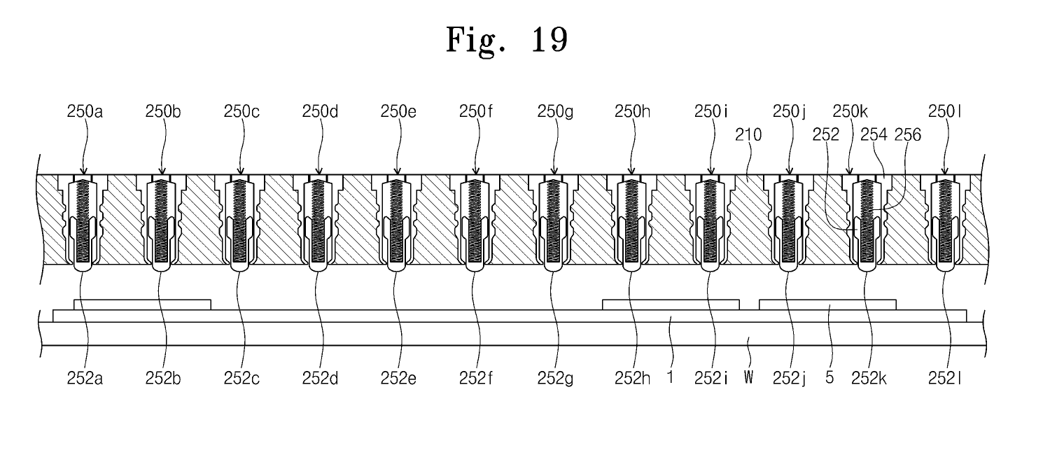

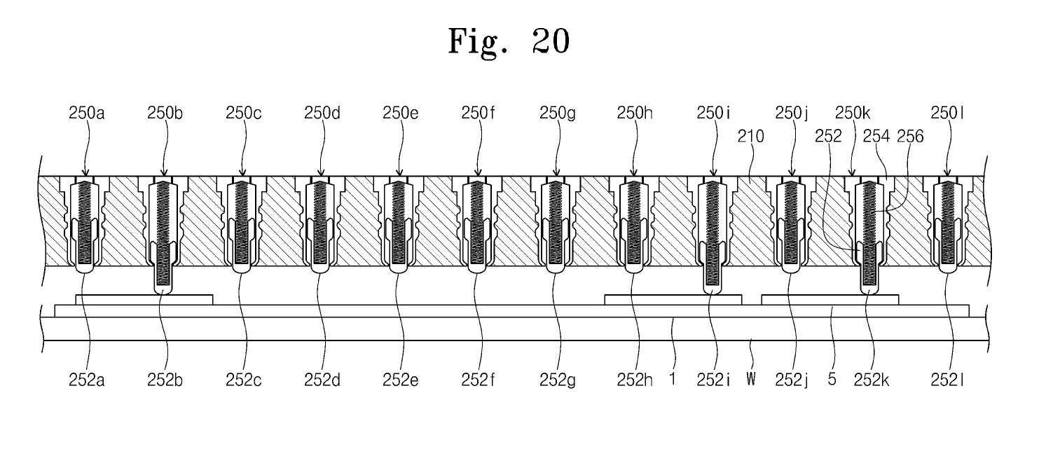

The wafer W shown in FIG. 19 differs from the wafers W of FIGS. 15 and 17, in terms of the arrangement and the number of the electrode pads 5. In this case, the first and second electrical signals generated by the tester 300 may be delivered to selected probe tips 252b, 252i, and 252k that are disposed over the electrode pads 5. As shown in FIG. 20, the probe tips 252b, 252i, and 252k may be referred to as the active probe tips. The pressure applying members 256 of the active probe tips may be elongated in response to the second electrical signals. Thus, the active probe tips may contact the corresponding electrode pads 5. The first electrical signals may then be delivered to the electrode pads 5, via the active probe tips.

As described above, the probe card 200 may perform a semiconductor device testing process on a variety of different wafers. As shown in FIGS. 15-20, the arrangement and/or number of the active probe tips may be changed, depending on the arrangement and/or number of the electrode pads 5 of the wafer W. The active probe tips may be selected based on an electrode pad pattern of a tested wafer. Alternatively, the active probe tips may be selected based on an electrode pad detection operation. Once the active probe tips are selected, the corresponding probe pins 250 may be activated by applying the electrical signals thereto, via the corresponding upper and lower terminals 132, 134 of the printed circuit board 130.

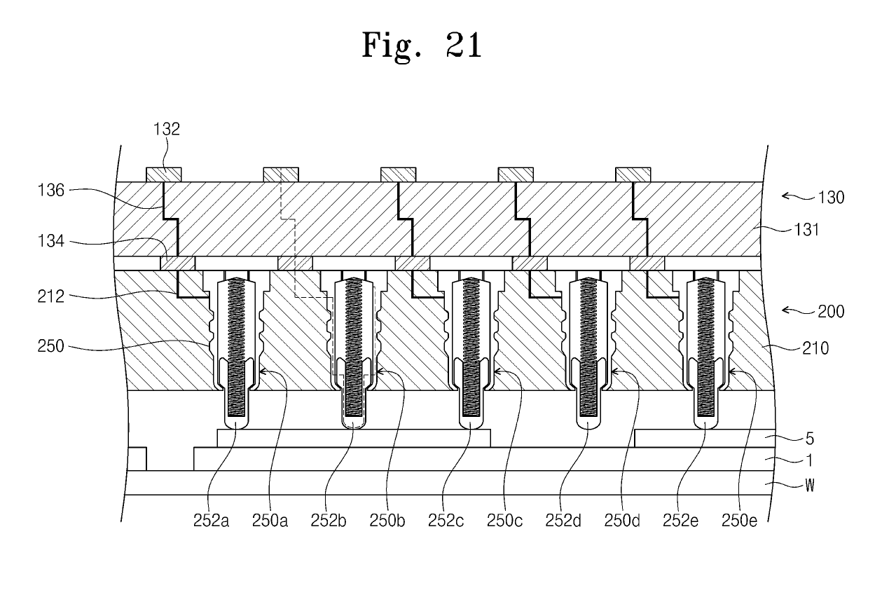

As illustrated in FIGS. 15 through 20, although more that one of the probe pins 250 are shown to be disposed over each of the electrode pads 5, only one of the probe pins 250 is extended to contact each electrode pad 5. According to other exemplary embodiments, more than one of the probe tips 250 may be extended to contact each of the electrode pads 5, as discussed below with regard to FIG. 21.

FIG. 21 is a schematic sectional view of the printed circuit board 130 engaged with the probe card 200, according to an exemplary embodiment of the general inventive concept. As shown in FIG. 21, all of the probe tips 250 of the probe card 200 may be extended toward the wafer 5. As such, more than one of the probe tips 252 may contact a corresponding one of the electrode pads 5.

As shown in FIG. 21, the first electrical signal, which is depicted by a dotted line, is only applied to probe tip 252b. Thus, the probe tip 252b may be referred to as an active probe tip, while probe tips 250a, 250c, 250d, and 250e may be referred to as inactive probe tips.

In other words, as shown in FIG. 21, all of the probe tips 252 may be extended toward the wafer W, such that independent control of the probe tips 252 is not required. Instead, the first electrical signals are selectively applied to the probe tips 252. The probe card 200 may be moved toward the wafer W, to bring the probe pins 250 into contact with the electrode pads 5, without independently extending the probe tips 252. The probe tips 252 may all be electrically extended, or the probe tips 252 may be fixed in an extended position. Accordingly, there is no need to independently generate the second signals, since the probe tips 252 are not independently extended. If the probe tips 252 are fixed in the extended position, the second electrical signals may be omitted. Moreover, some of the upper terminals 132, the lower terminals 134, and the signal interconnection lines 136, may not be used during the electrical test of the semiconductor device 1.

Therefore, according to various embodiments, in order to bring the probe pins 250 into contact with the electrode pads 5, all, some, or none of the probe tips 252 may be electrically extended from the probe card 200 toward the wafer W. When the probe tips 252 are not independently extended, the first electrical signals may be applied to selected ones of the probe tips, such that the selected probe tips 252 may be active probe tips used for the electrical testing of the semiconductor device 1.

According to exemplary embodiments of the inventive concept, a process of electrically testing the semiconductor device 1 can be performed with high efficiency.

According to various embodiments, one probe card may be used to electrically test a variety of semiconductor devices, which may have different configurations.

Although a few exemplary embodiments of the present general inventive concept have been shown and described, it will be appreciated by those skilled in the art that changes may be made in these exemplary embodiments, without departing from the principles and spirit of the general inventive concept, the scope of which is defined in the appended claims and their equivalents.

What is claimed is:

1. A semiconductor device testing system, comprising:
a tester configured to evaluate electrical characteristics of a semiconductor device provided on a wafer, using electrical signals; and
a probe unit configured to transfer the electrical signals between the tester and the semiconductor device, the probe unit comprising:
a housing;
a wafer supporting member disposed in the housing and to support the wafer;
a printed circuit board disposed on the housing and to transfer the electrical signals; and
a probe card disposed in the housing and to transfer the electrical signals between the semiconductor device and the printed circuit board, the probe card comprising probe pins configured to selectively extend from the probe card to electrically contact the semiconductor device.

2. The system of claim 1, wherein the probe pins comprise:
probe tips to contact the semiconductor device; and
pressure applying members to selectively extend the probe tips from the probe card.

3. The system of claim 2, wherein the pressure applying members are actuated to move the probe tips into contact with electrode pads of the semiconductor device.

4. The system of claim 2, wherein the pressure applying members are actuated in response to the electrical signals.

5. The system of claim 2, wherein the pressure applying members comprise piezo-electric elements.

6. The system of claim 2, wherein the pressure applying members are spring-shaped.

7. The system of claim 2, wherein:
the electrical signals comprise first electrical signals for controlling the pressure applying members, and second electrical signals for testing the semiconductor device; and
the system further comprises different signal lines to transmit the first electrical signals and the second electrical signals.

8. The system of claim 1, wherein the wafer supporting member comprises:
a plate to support the wafer;
a heating part to heat the plate; and
a cooling part to cool the plate.

9. The system of claim 1, wherein:
the probe pins each comprise:
a cylindrical probe tip having an open upper end;
a tubular outer body in which the probe tip is disposed; and
a pressure applying member disposed in the outer body and the probe tip; and
the probe card further comprises a supporting board comprising through holes in which the probe pins are disposed.

10. The system of claim 1, wherein the probe card is inserted into joining grooves formed in opposing inner surfaces of the housing.

11. The system of claim 1, wherein the printed circuit board comprises:
first signal lines to transfer the electrical signals between the probe pins and the tester, to electrically test the semiconductor device; and
second signal lines to transfer the electrical signals between the probe pins and the tester, to actuate the probe pins.

12. The system of claim 11, wherein the printed circuit board further comprises first lower terminals connected to the first lines, and second lower terminals connected to the second lines, the first and second lower terminals being configured to electrically connect with the probe card.

13. A method of testing the electrical characteristics of a wafer including a semiconductor device, using a probe card including probe pins, the density of the probe pins being greater than that of electrode pads of the wafer, the method comprising:
dividing the probe pins into active probe pins and inactive probe pins; and
evaluating the electrical characteristics of the wafer using only the active probe pins.

14. The method of claim 13, wherein the evaluating of the electrical characteristics of the wafer further comprises contacting the electrode pads with only the active probe pins.

15. The method of claim 14, wherein the contacting of the electrode pads comprises actuating pressure applying members of the active probe pins to extend the active probe pins, so as to contact the electrode pads.

16. The method of claim 14, wherein the contacting of the electrode pads comprises actuating pressure applying members of the active probe pins to extend the probe tips of the active probe pins, such that each of the electrode pads is contacted by only one of the probe tips.

17. A system to test a semiconductor device, comprising:
a printed circuit board; and
a probe card configured to transfer electrical signals between the printed circuit board and a semiconductor device, the probe card comprising a supporting board and probe pins disposed in the supporting board, the probe card configured to divide the probe pins into active probe pins configured to deliver the electrical signals to the semiconductor device, and inactive probe pins not configured to deliver the electrical signals to the semiconductor device, according to the configuration of the semiconductor device.

18. The system of claim 17, wherein the probe pins each comprise:
an extendable probe tip;
an outer body disposed in the probe card and to house the probe tip; and
a pressure applying member to selectively extend the probe tip toward the semiconductor device.

19. The system of claim 18, wherein the electrical signals comprise:
first signals to evaluate the electrical characteristics of the semiconductor device; and
second signals to control the pressure applying members.

20. The system of claim 17, wherein:
the probe card comprises a greater number of the electrode pins than a number of electrode pads comprised by the semiconductor device; and
tester produces the electrical signals for only one of the electrode pins per electrode pad.
